(19) United States
(12) Patent Application Publication
(10) Pub. No.: US 2017/0307928 A1
(43) Pub. Date: Oct. 26, 2017

(54) DISPLAY DEVICE

(71) Applicant: KONICA MINOLTA, INC., Tokyo (JP)

(72) Inventors: Kazuyoshi OMATA, Akishima-shi, Tokyo (JP); Tsukasa YAGI, Kobe-shi, Hyogo (JP)

(21) Appl. No.: 15/518,405

(22) PCT Filed: Oct. 20, 2015
(86) PCT No.: PCT/JP2015/079577

§ 371 Date: Apr. 11, 2017

(30) Foreign Application Priority Data
Oct. 21, 2014 (JP) 2014-214825

(51) Int. Cl. G02F 1/137; G02F 1/061; G02F 1/03; G02F 1/1335

(52) U.S. Cl. CPC G02F 1/13762; G02F 1/061; G02F 1/0316; G02F 1/133602; G02F 1/133514

(57) ABSTRACT

Provided is a display device that can perform stable field-sequential drive. The display device is provided with a backlight (100) and with a field-sequential display panel (200). The backlight has light-emitting units that are organic electroluminescence elements that can emit light of the three primary colors red, green, and blue. At least one electrode of the organic electroluminescence elements comprises Ag or an alloy that includes Ag as a principal component.

### TECHNICAL FIELD

The present invention relates to a display device of a field-sequential system which is provided with an organic electroluminescence element (organic EL element) as a light source.

### BACKGROUND ART

There is proposed a display device of a field-sequential system as display devices. The field-sequential system is a system to which there is applied the fact that light beams of two or more colors are emitted by being continually switched over and the switching speed is set to a speed that exceeds a human eye's temporal resolution, and the human eye perceives the above-described two or more colors by mixing them. The field-sequential system is a color display system utilizing a color mixture on the basis of “time-division.”

In the display device of the field-sequential system, there is proposed an organic electroluminescence (EL) element instead of an LED as a directly-under type backlight or a side-edge type backlight (for example, refer to Patent Literature 1, Patent Literature 2).

The display device of the field-sequential system gives, in the moving image display, arbitrary colored light by enabling light emission of anyone color of red (R) color, green (G) color, and blue (B) color constituting back light, by emitting light through switching over (time-dividing) respective colors continually for each field, and by making the switching speed sufficiently high.

For example, each field of color is divided into a state of being spectrally separated into an R field, a G field, and a B field, and the respective fields of R, G, and B are each caused to emit light sequentially with time lags to thereby display one color field on the display panel. At this time, when the R field is displayed, the light emission of the backlight is set to red (R), when the B field is displayed, the light emission of the backlight is set to blue (B), and when the G field is displayed, the light emission of the backlight is set to green (G).

It is possible to display color moving images by continually displaying each of the three-color fields which are time-divided in the above-described way while switching over the emission colors.

Since the display device of the field-sequential system causes less loss of light due to absorption than the system in which the color filter is used, and does not use an expensive color filter, and thus the system has a great advantage because of being able to reduce the number of parts and of cost reduction.

### CITATION LIST

### Patent Literature

PTL 1: Japanese Patent Laid-Open No. 2008-66366

PTL 2: Japanese Patent Laid-Open No. 2007-172945

### SUMMARY OF INVENTION

### Technical Problem

In the display device of the field-sequential system, since the display panel is driven at a high speed by the field-sequential system, it is necessary to drive the organic EL element at a speed corresponding to the high-speed driving of the display panel.

However, in the above field-sequential liquid crystal display device of the described in Patent Literature 1 and Patent Literature 2, an ITO (Indium Tin Oxide) is used as a transparent electrode of the organic EL element used for the backlight. In a case of using ITO as the transparent electrode of the organic EL element, the transparent electrode has a high electric resistance, a sufficient driving speed required by the field-sequential system cannot be obtained, and thus the driving of the organic EL element may become unstable.

Accordingly, in a case of using the organic EL element including the transparent electrode of ITO as the backlight, the driving of the display device becomes unstable.

In order to solve the above-described problems, the present invention provides a display device capable of stable driving in the field-sequential system.

### Solution to Problem

The display device of the present invention includes backlight and a display panel of the field-sequential system. In addition, a light-emitting portion of the backlight is an organic electroluminescence element including a plurality of light-emitting units that emit light of different colors, and at least one of electrodes of the organic electroluminescence elements is composed of Ag or an alloy containing Ag as a principal component.

### Advantageous Effects of Invention

According to the present invention, a display device capable of stable driving can be provided.

### BRIEF DESCRIPTION OF DRAWINGS

FIG. 1 is a schematic configuration diagram of a display device of a first embodiment.

FIG. 2 is a plane arrangement diagram of backlight used in the display device.

FIG. 3 is a schematic configuration diagram of the display device of a second embodiment.

FIG. 4 is an equivalent circuit chart and a timing chart of an organic EL element.

### DESCRIPTION OF EMBODIMENTS

Hereinafter, the embodiments for the present invention will be explained, but the present invention is not limited thereto.

Note that the explanation is made in the following order.

1. First embodiment of display device

2. Second embodiment of display device

3. Timing chart

### 1. First Embodiment of Display Device

FIG. 1 is a schematic configuration diagram of a display device capable of applying the field-sequential system. The display device shown in FIG. 1 is provided with a backlight 100 including a display panel 200 and an organic electroluminescence element (organic EL element).

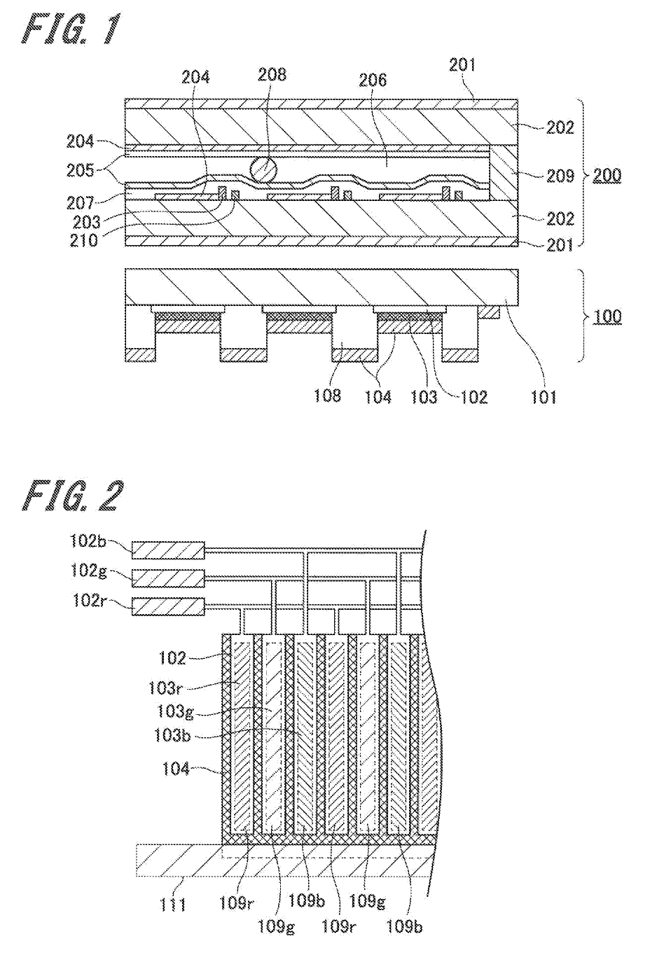

FIG. 2 shows plane arrangement of the backlight 100 used in the display device.

### Display Panel

The display panel 200 is a display panel for the field-sequential system which can be driven at a high speed by a TFT (Thin Film Transistor) system. The display panel 200 has a known configuration in the TFT system, and the display panel 200 is configured by sandwiching a liquid crystal layer 206 between two transparent substrates 202 (for example, glass substrate or transparent film substrate) which have a polarizing plate 201 on the outer surface side.

Pixel electrodes 204 and thin film transistors (TFT) 203 are formed on the lower transparent substrate 202. Furthermore, there are arranged, on the transparent substrate 202, data lines 210 and scanning lines (not shown) in a matrix manner via an insulating layer 207. In addition, there are arranged the TFT 203 and the pixel electrode 204 at the crossing point of the data line 210 and the scanning line.

Furthermore, a highly responsible liquid crystal layer 206 sandwiched by oriented films 205, above the insulating 207. In the liquid crystal layer 206, there is configured a space for sealing the liquid crystal layer 206, by a spacer 208, a seal 209 and a pair of the oriented films 205.

In order to display a full color image by the field-sequential system, a highly responsible one is required as the display panel 200, and it is preferable to use a highly responsible liquid crystal display panel utilizing a known ferroelectric liquid crystal or an anti-ferroelectric liquid crystal, and a liquid crystal panel of OCB (Optically Compensated Bend, Optically Compensated Birefringence) type. Furthermore, a liquid crystal panel of MEMS (Micro Electro Mechanical Systems) type may be used. Note that the display panel 200 has a configuration of not having a color filter in order to carry out application to the display device of the field-sequential system.

### Backlight

Next, the backlight 100 used for the field-sequential system shown in FIG. 1 will be explained. A light-emitting portion of the backlight 100 is configured by a belt-like organic EL element. These belt-like organic EL elements are arranged in parallel in the direction of the light-emitting-surface sidel.

There are formed, on a transparent substrate 101, a first electrode 102 made of a belt-like and stripe-like transparent electrode is formed approximately in parallel, and a partition wall 108 which is made of an insulating material. The partition wall 108 is formed along the first electrode 102, and is arranged while an opening is left on the first electrode 102. There is formed, on the first electrode 102, light-emitting units 103r, 103g, and 103b including light-emitting layers which emit red light, green light, blue light. There is accumulated in accordance with the level difference, on the light-emitting units 103r, 103g, and 103b and the partition wall resist, a second electrode 104 of a backside electrode over the transparent substrate 101 of the peripheral.

Furthermore, in the organic EL element, the first electrode 102 and the second electrode 104 sandwich the light-emitting units 103r, 103g, and 103b, and one electrode acts as a cathode and the other acts as an anode. In addition, the overlapped portion of the first electrode 102, the light-emitting unit 103r and the second electrode 104 is formed as one organic EL element. In a similar way, the overlapped portion of the first electrode 102, the light-emitting unit 103g and the second electrode 104 is formed as one organic EL element, and the overlapped portion of the first electrode 102, the light-emitting unit 103b and the second electrode 104 is formed as one organic EL element.

FIG. 2 shows stripe-like organic EL regions 109r, 109g, and 109b which emit each light of R, G, B formed as the backlight 100. The organic EL regions 109r, 109g, and 109b correspond to the organic EL elements composed of the first electrode 102, the light-emitting units 103r, 103g, and 103b, and the second electrode 104 shown in FIG. 1, respectively. Areas of the organic EL regions 109r, 109g, and 109b may be within the range in which each stripe-forming periodic cycle is averaged at the time of time-division driving and thus there is no problem of white display. Notte that FIG. 2 shows the schematic backlight 100, and actually, many belt-like organic EL regions 109r, 109g, 109b each having emission colors of red, green, blue are arranged in parallel.

The first electrode 102 is connected to first terminals 102r, 102g, 102b for each emission color through wiring portions made of the same material of the first electrode 102. For example, the first electrode 102 having the organic EL region 109r having an emission color of red is connected to the first terminal 102r through the wiring portion, the first electrode 102 having the organic EL region 109b having an emission color of blue is connected to the first terminal 102b through the wiring portion, and the first electrode 102 having the organic EL region 109g having an emission color of green is connected to the first terminal 102g through the wiring portion, respectively.

The first terminals 102r, 102g, and 102b are formed on transparent substrate 101 on the side of the first electrode 102, and the number thereof is the same as the number of the emission color of the organic EL regions 109r, 109g, and 109b. Then, each of the first terminals 102r, 102g, and 102b is connected to one end portion of the first electrode 102 which corresponds to the same emission color, via the wiring portion.

Namely, all of the first electrodes 102 of the organic EL region 109r having an emission color of red are connected electrically to the first terminal 102r for emitting red light. In addition, all of the first electrodes 102 of the organic EL region 109g having an emission color of green are connected electrically to the first terminal 102g for emitting green light. All of the first electrodes 102 of the organic EL region 109b having an emission color of blue are connected electrically to the first terminal 102b for emitting blue light.

Therefore, it is possible to individually drive the organic EL regions 109r, 109g, and 109b each having emission colors of R, G, B, by individually driving and controlling each of the first terminals 102r, 102g, and 102b. In addition, it becomes possible to change the brightness for the organic EL regions 109r, 109g, and 109b each having emission colors.

Furthermore, as shown in FIG. 2, a second terminal 111 electrically separated away from the first electrode 102 is formed adjacent to the organic EL regions 109r, 109g, and 109b. The second electrode 104 is connected to the second terminal 111 by an electrically conductive layer. The second terminal 111 is connected to an external circuit to supply a determined voltage.

In the backlight of the display device of the field-sequential system, the light emission is caused through the time-division driving by switching of the organic EL regions 109r, 109g, and 109b. In the display device, it is necessary to switch the field at about 1/60 second or less in order not to generate flicker of images due to the color switching. Therefore, in order to display one color per one field by the use of the organic EL element of the above configuration, at least it is necessary to perform time-division driving of the organic EL regions 109r, 109g, and 109b at least at about 1/180 second or less, namely, about 6 milliseconds or less.

In the time-division driving of the organic EL element, each light of R, G, and B colors is emitted by the drive and control of the first terminals 102r, 102g, and 102b, respectively. For example, all of the first electrodes 102 in the organic EL region 109r, all of the first electrodes 102 in the organic EL region 109g and all of the first electrodes 102 in the organic EL region 109b are subjected to time-division driving for each emission color.

### Organic EL Element

Next, the configuration of the organic EL element constituting the light-emitting portion of the backlight will be explained.

The organic EL element includes the first electrode 102 and the second electrode 104, and the units 103r, 103g, and 103b which contain organic materials having light emission properties between the electrodes. In addition, these configurations are provided on the transparent substrate 101.

Furthermore, the first electrode 102 is constituted as a translucent electrode, in the organic EL element. In the configuration, only a portion where the light-emitting unit 103 is sandwiched by the first electrode 102 and the second electrode 104 is light-emitting regions in the organic EL element. In addition, the organic EL element is constituted as a bottom-emission type in which light generated is extracted at least from the transparent substrate 101 side.

Hereinafter, these configurations will be explained in detail.

### Substrate

The substrate 101 of the organic EL element can include, for example, a glass, plastics, and the like, but is not limited thereto. A preferable transparent substrate 101 can include a glass, a quartz, and a transparent resin film.

Examples of the resin film include: polyesters such as polyethylene terephthalate (PET) and polyethylene naphthalate (PEN); polyethylene; polypropylene; cellulose esters or derivative thereof such as cellophane, cellulose diacetate, cellulose triacetate (TAC), cellulose acetate butylate, cellulose acetate propionate (CAP), cellulose acetate phthalate and cellulose nitrate; polyvinylidene chloride; polyvinyl alcohol; polyethylene vinyl alcohol; syndiotactic polystyrene; polycarbonate; norbornen resin; polymethylpenten; polyether ketone; polyimide; polyether sulphone (PES); polyphenylene sulfide; polysluphones; polyether imide; polyether ketone imide; polyamide; fluoro resin; Nylon; polymethyl methacrylate; acryl or polyallylates; cycloolefins-based resins such as Alton (commercial name of JSR) or APEL (commercial name of Mitsui Chemicals).

### First Electrode

The first electrode 102 is the transparent electrode in the organic EL element and is an electrically conductive layer constituted by the use of silver or an alloy containing silver as a principal component. Here, the principal component means a component having the highest composition ratio among the components constituting the first electrode 102.

Examples of the alloys consituting the first electrode 102 and containing silver (Ag) as a principal component include silver magnesium (AgMg), silver copper (AgCu), silver palladium (AgPd), silver palladium copper (AgPdCu), silver indium (AgIn), and the like.

The first electrode 102 may have a configuration of laminated layers in which the layers of silver or the alloy containing silver as a principal component are laminated by being divided into a plurality of layers, as necessary.

Furthermore, the layer thickness of the first electrode 102 is preferably within the range of 2 to 15 nm, more preferably within the range of 3 to 12 nm, and particularly preferably within the range of 4 to 9 nm. When the layer thickness is less than 15 nm, the absorbing components or the reflective components of the layer are small, and thus light transmittance of the first electrode 102 becomes large. In addition, when the layer thickness is more than 2 nm, it is possible to sufficiently ensure the conductivity of the layer.

The method for depositing the first electrode 102 includes a method using a wet process such as an applying method, an inkjet method, a coating method or a dipping method, or a method using a dry process such as a vapor deposition method (resistance heating, an EB method, and the like), a sputtering method, or a CVD method. Among them, the vapor deposition method is preferably employed.

### Underlayer

In addition, the first electrode 102 constituted by the use of silver or the alloy containing silver as a principal component is preferably formed on the following underlayer. The underlayer is a layer provided on the transparent substrate 101 side of the first electrode 102.

The material constituting the underlayer is not particularly limited, and includes: a compound or the like which can suppress the aggregation of silver and which contains nitrogen atom or sulfur atom, in the deposition of, for example, the first electrode 102 composed of silver or the alloy containing silver as a principal component; a layer containing metals such as Pd, Al, Ti, Pt and Mo which serve as a growth nucleus in the deposition of silver; and a layer containing zinc oxide.

In a case where the underlayer is composed of a material having a low refractive index (refractive index of less than 1.7), the upper limit of the thickness is required to be less than 50 nm, preferably less than 30 nm, further preferably less than 10 nm, and particularly preferably less than 5 nm. When the thickness is less than 50 nm, the optical loss is minimized. On the other hand, the lower limit of the thickness is required to be 0.05 nm or more, preferably 0.1 nm or more, and particularly preferably 0.3 nm or more. When the thickness is 0.05 nm or more, it is possible to achieve uniform deposition of the underlayer and to uniformly achieve the effect (suppression of aggregation of silver).

In a case where the underlayer is composed of a material having a high refractive index (refractive index of 1.7 or more), the upper limit is not particularly limited, and the lower limit of the thickness is the same as the case of the above material having a low refractive index.

However, it is sufficient that the underlayer is formed having a necessary thickness that gives uniform deposition, simply as a function of the underlayer.

In a case where the underlayer is a layer including a metal serving as a growth nucleus of silver, the thickness of the layer is a thickness that does not inhibit the light transmittance of the organic EL element, and may be preferably, for example, 5 nm or less. In contrast, the underlayer is required to have a thickness that can ensure the film uniformity of the first electrode 102. The underlayer having a thickness like this may be a layer in which each metal atom forms at least one atomic layer. Furthermore, the underlayer is preferably a continuous layer. Note that, in the underlayer, even if defects exist in the continuous phase of the layer including the metal serving as a growth nucleus of silver, it is possible to ensure a film uniformity of the first electrode 102 as long as the defect is smaller than the Ag atom constituting the first electrode 102.

The nitrogen-containing compound constituting the underlayer is not particularly limited as long as the compound contains a nitrogen atom within the molecule, and is preferably a compound having a heterocyclic ring containing a nitrogen atom as the hetero atom. Examples of the heterocyclic rings containing a nitrogen atom as the hetero atom include aziridine, azirine, azetidine, azete, azolidine, azoles, ajinan, pyridine, azepane, azepine, imidazole, pyrazole, oxazole, thiazole, imidazoline, pyrazine, morpholine, thiazine, indole, isoindole, benzimidazole, purine, quinoline, isoquinoline, quinoxaline, cinnoline, pteridine, acridine, carbazole, benzo-C-cinnoline, porphyrins, chlorins, choline, and the like.

Examples of the methods for deposition of the underlayer include: a method using a wet process such as an application method, an inkjet method, a coating method, or a dipping method; a method using a dry process such as a vapor deposition method (resistance heating, EB method, and the like) , a sputtering method, an ion-plating method, a plasma CVD method or a heat CVD method; and the like. Among them, the under layer is preferably formed by an electron beam vapor deposition method or a sputtering method, from the viewpoint of deposition property. In the case of the electron beam vapor deposition method, it is preferable to use an assist such as IAD (ion assist), or the like in order to enhance the film density.

Furthermore, the layer including zinc oxide (zinc oxide-containing layer) constituting the underlayer contains zinc oxide (ZnO) as a principal component. Here, the principal component in the zinc oxide-containing layer is a component having the highest percentage among the components constituting the layer, and the percentage is preferably 50% by atom or more. It is possible to make uniform the alignment of the silver atoms contained in the first electrode 102 and to achieve both of light transmittance and resistance property, by the use of the zinc oxide-containing layer as the underlayer of the first electrode 102.

In the zinc oxide-containing layer may contain materials other than zinc oxide. A dielectric material or an oxide semiconductor material as the materials other than zinc oxide contained in the zinc oxide-containing layer may be an insulation material or a conductive material. Examples of the dielectric material or the oxide semiconductor material contained in the zinc oxide-containing layer include TiO₂, ITO (indium-tin oxide) , ZnS, Nb₂O₅, ZrO₂, CeO₂, Ta₂O₅, Ti₃O₅, Ti₄O₇, Ti₂O₃, TiO, SnO₂, La₂Ti₂O₇, IZO (indium oxide-zinc oxide), AZO (Al-doped ZnO), GZO (Ga-doped ZnO), ATO (Sb-doped SnO), ICO (indium cerium oxide), Ga₂O₃, and the like. The zinc oxide-containing layer may contain the dielectric material or the oxide semiconductor material of one kind or two or more kinds. The dielectric material or the oxide semiconductor material is particularly preferably ZnS, TiO₂, GZO or ITO.

Note that the zinc oxide-containing layer may contain MgF₂, SiO₂, and the like other than the above dielectric material or the oxide semiconductor material. For example, the zinc oxide-containing layer contains SiO₂, the layer easily becomes amorphous, and flexibility of the organic EL element is easily enhanced.

The zinc oxide-containing layer preferably contains zinc oxide as a principal component from the viewpoint of suppressing the aggregation of silver at the time of the deposition of the first electrode 102 and of obtaining the first electrode 102 having a small thickness but a uniform thickness. The amount of zinc atom contained in the zinc oxide-containing layer is preferably 0.1 to 50 at %, more preferably 0.5 to 50 at % relative to the whole atoms constituting the zinc oxide-containing layer.

On the other hand, when the amount of the zinc atom is excessive, it becomes difficult to uniformly deposit the zinc oxide-containing layer, and thus there is a case where the transparency is lowered. The types and contents of the respective atoms contained in the first electrode 102 are specified by, for example, an XPS method, and the like.

Generally, the thickness of the zinc oxide-containing layer is preferably 3 to 35 nm, more preferably 5 to 25 nm. When the thickness of the zinc oxide-containing layer is 3 nm or more, a deposition property of the first electrode 102 is sufficiently enhanced. On the other hand, when the thickness of the zinc oxide-containing layer is 35 nm or less, there is a small influence of the organic EL element on the optical properties, the light transmittance of the organic EL element is difficult to be lowered. The thickness of the zinc oxide-containing layer is measured by an ellipsometer, or the like.

Although the first electrode 102 has a feature of having, by deposition on the underlayer, sufficient conductivity even without a high temperature annealing treatment after the deposition of the first electrode 102, the first electrode may be subjected to the high temperature annealing treatment after the deposition as necessary.

When the first electrode 102 having Ag as a principal component is formed on the substrate, the Ag atoms adhering to the substrate form a mass (core) having a certain size while being diffused on the surface. Then, initial growth of a thin film proceeds along a periphery of the mass (core). Accordingly, the film of the initial stage is not electrically conductive since there is a space between the masses. When the masses further grow from the state and each of the thicknesses of the masses becomes about 15 μm, parts of the masses are connected to each other and become barely electrically conductive. However, the surface of the film is not yet flat, plasmon absorption is easily generated.

In contrast, when there is previously formed, as the underlayer, a layer containing a metal serving as a growth nucleus in the deposition of silver, such as Pd, Al, Ti, Pt or Mo, the metal material such as Ag constituting the first electrode 102 becomes difficult to move on the underlayer. Furthermore, the metal such as Pd can make the space between growth nuclei narrower than the space between the masses formed through the surface diffusion of the Ag atoms. Therefore, when the Ag layer grows from the Pd growth nucleus, the obtained film becomes easily flat even if the thickness is small.

Moreover, it is possible to have a configuration in which, for example, the first electrode 102 of silver or the alloy containing silver as a principal component is provided on the underlayer constituted by the use of the compound containing a nitrogen atom. Accordingly, in depositing the first electrode 102 on the underlayer, the silver atom constituting the first electrode 102 interacts with the compound containing a nitrogen atom constituting the underlayer, the diffusion distance of the silver atom on the surface of the underlayer becomes short, and thus the aggregation of the silver is suppressed.

In addition, the zinc atom contained in the zinc oxide-containing layer has an affinity with the silver of the first electrode 102. Therefore, at the time of the deposition of the first electrode 102, the silver constituting the first electrode 102 becomes hard to be aggregated on the zinc oxide-containing layer, and thus it is possible to form the thin and uniform first electrode 102. Furthermore, since the zinc atom has an affinity with the silver contained in the first electrode 102, it is possible to suppress the aggregation of the silver due to moisture under a high humidity circumstance, and corrosion of the silver.

Namely, in the deposition of the silver in which the silver particle is easily isolated in an island shape by the nucleus-growth type (Volmer-Weber: VW-type), the aggregation of the silver to be deposited is suppressed by the use of the underlayer. Accordingly, in the deposition of the first electrode 102 composed of silver or the alloy containing silver as a principal component, the thin film grows according to the mono-layer growth type (Frank-van der Merwe: FM type). Therefore, as described above, the first electrode 102 composed of silver or the alloy containing silver as a principal component assures electric conductivity at a smaller thickness, and it becomes possible to achieve both of the enhancement of the conductivity and the enhancement of the light transmittance, in the first electrode 102.

### Second Electrode

The second electrode 104 is an electrode film having, for example, a function that supplies electrons to the light-emitting units 103r, 103g, and 103b and serving as a counter electrode with respect to the first electrode 102 being a transparent electrode. There is used, as the second electrode 104, an electrode composed of an electrode material having a low work function (4 eV or less) such as a metal (referred to as an electron-injecting metal), an alloy, an electrically conductive compound, or a mixture thereof.

The sheet resistance as the second electrode 104 is preferably several Q/square or less, and the thickness thereof is selected usually within the range of 10 nm to 5 μm, preferably in the range of 50 nm to 200 nm.

Specific examples of such electrode materials as described above include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, a rare earth metal, and the like.

Among them, from the viewpoint of electron injection property and durability against oxidation, preferred examples are a mixture of the electron-injecting metal and a secondary metal that is a metal having a work function higher than that of the electron-injecting metal and being more stable, such as a magnesium/silver mixture, a magnesium/aluminum mixture, a magnesium/indium mixture, an aluminum/aluminum oxide (Al₂O₃) mixture, a lithium/aluminum mixture, aluminum, and the like.

The second electrode 104 can be fabricated by formation of each of thin films of the electrode materials by a method such as vapor deposition or sputtering.

### Light-Emitting Unit

The light-emitting units 103r, 103g, and 103b may contain at least a luminescent organic material, and may have a light-emitting layer that emits light of red color, green color or blue color, and further may have other layer between the Light-emitting layer and the electrode.

Representative element configurations of the light-emitting units 103r, 103g, and 103b are as follows, but the present invention is not limited thereto.

(1) Anode/light-emitting layer/cathode

(2) Anode/light-emitting layer/electron transport layer/cathode

(3) Anode/positive hole transport layer/light-emitting layer/cathode

(4) Anode/positive hole transport layer/light-emitting layer/electron transport layer/cathode

(5) Anode/positive hole transport layer/light-emitting layer/electron transport layer/electron injection layer/cathode

(6) Anode/positive hole injection layer/positive hole transport layer/light-emitting layer/electron transport layer/cathode

(7) Anode/positive hole injection layer/positive hole transport layer/(electron-blocking layer)/light-emitting layer/(positive hole-blocking layer)/electron transport layer/electron injection layer/cathode

Among them, the configuration (7) is preferably used, but the present invention is not limited thereto.

In the above representative element configurations, layers other than the anode and cathode are the light-emitting units.

### Light-Emitting Unit

In the above configuration, the light-emitting layer is composed of a mono-layer or multi-layer. When the light emitting-layer is plural, a non-light-emitting intermediate layer may be provided between the light-emitting layers.

As necessary, a positive hole-blocking layer (positive hole barrier layer), an electron injection layer (cathode buffer layer) or the like may be provided between the light-emitting layer and the cathode, and an electron-blocking layer (electron barrier layer), a positive hole injection layer (anode buffer layer) or the like may be provided between the light-emitting layer and the anode.

The electron transport layer is a layer having a function of transporting an electron. The electron transport layer also includes the electron injection layer, and the positive hole-blocking layer, in a broad sense. Furthermore, the electron transport layer may be composed of plural layers.

The positive hole transport layer is a layer having a function of transporting a positive hole. The positive hole transport layer also includes the positive hole injection layer, and the electron-blocking layer, in a broad sense. Furthermore, the positive hole transport layer may be composed of plural layers.

### Light-Emitting Layer

In the light-emitting layer, it is preferable to contain a phosphorescence-emitting compound as the light-emitting material. Furthermore, the light-emitting layer may be used by mixture of a plurality of light-emitting materials, or by mixture of a phosphorescence-emitting compound and a fluorescence-emitting material (fluorescent dopant, fluorescent compound) in the same light-emitting layer. It is preferable that the light-emitting layer contains a host compound (emitting host, and the like) and a light-emitting material (light-emitting dopant) as its configuration, and emit light by the use of the light-emitting material. The above light-emitting layer can be formed through deposition of the light-emitting material and the host compound, by a well-known thin film forming method such as a vacuum vapor deposition method, a spin coating method, a casting method, an LB method or an inkjet method.

The configuration of the light-emitting layer is not particularly limited as long as the light-emitting material contained therein satisfies a light emission requirement. The light-emitting layer is a layer that emits light by recombination of electrons injected from an electrode or an electron transport layer, and positive holes from the positive hole transport layer, and a portion that emits light may be either the inside of the light-emitting layer or an interface between the light-emitting layer and its adjacent layer. Furthermore, there may be a plurality of light-emitting layers having the same emission spectrum or emission maximum wavelength. In such a case, a non-luminescent auxiliary layer may be present between the light-emitting layers.

The total thickness of the light-emitting layers is preferably within a range of 1 to 100 nm and, more preferably within a range of 1 to 30 nm from the viewpoint of being capable of obtaining a lower driving voltage. In a case of the light-emitting layer having a configuration obtained by lamination of a plurality of layers, it is preferable to adjust the thickness of individual light-emitting layer to be within a range of 1 to 50 nm and it is more preferable to adjust the thickness thereof to be within a range of 1 to 20 nm. Note that the total thickness of the light-emitting layers has a thickness including the thickness of the intermediate layers, in a case where non-luminescent intermediate layers are present between the light-emitting layers.

(1) Host Compound

The preferable host compound contained in the light-emitting layer is preferably a compound having, in phosphorescence emission at room temperature (25° C.), a phosphorescence quantum yield of less than 0.1. More preferable phosphorescence quantum yield is less than 0.01. Furthermore, a compound having a volume ratio of 50% or more in the light-emitting layer is preferable, among the compounds contained in the layer.

A well-known host compound may be used alone or in combination of a plurality of kinds, as the host compound. It is possible to adjust transfer of charges and increase an efficiency of the organic EL element, by the use of a plurality of the host compounds. Furthermore, it becomes possible to mix different colors of light to be emitted, by the use of a plurality of light-emitting materials mentioned below, and thus an arbitrary emission color can be obtained.

(2) Light-Emitting Material

A phosphorescence-emitting compound (phosphorescent compound, phosphorescence-emitting material) and fluorescence-emitting compound (fluorescent compound, fluorescence-emitting material) can be used as the light-emitting material.

### Phosphorescence-Emitting Compound

The phosphorescence-emitting compound is defined as a compound in which light emission from an excited triplet state is observed, and, specifically, a compound that emits phosphorescence at room temperature (25° C.), and a phosphorescence quantum yield at 25° C. is 0.01 or more, and preferable phosphorescence quantum yield is 0.1 or more.

The above-described phosphorescence quantum yield can be measured by a method described on page 398 of Bunko II of Dai 4 Han Jikken Kagaku Koza 7 (1992, published by Maruzen Co., Ltd.). The phosphorescence quantum yield in a solution can be measured by the use of various solvents, and when the phosphorescence-emitting compound is used, it is sufficient to achieve the above-described phosphorescence quantum yield (0.01 or more) in any of appropriate solvents.

The phosphorescence-emitting compound can be used by suitable selection from the well-known phosphorescence-emitting compounds used for light-emitting layers of organic EL elements. The phosphorescence-emitting compound is preferably a complex-based compound containing a metal of the groups 8 to 10 in the element periodic table, and more preferable is an iridium compound, an osmium compound, a platinum compound (a platinum complex compound) or a rare earth complex, and most preferable is an iridium compound.

At least one light-emitting layer may contain two or more types of light-emitting materials, and a ratio of concentration of the phosphorescence-emitting compound in the light-emitting layer may vary in the direction of thickness of the light-emitting layer. An amount of the phosphorescence-emitting compound is preferably 0.1% or more by volume and less than 30% by volume relative to the total volume of the light-emitting layer.

### Fluorescence-Emitting Compound

Examples of the fluorescence-emitting compound include a coumarin-based dye, a pyran-based dye, a cyanine-based dye, a croconium-based dye, a squarylium-based dye, an oxobenzanthracene-based dye, a fluorescein-based dye, a rhodamine-based dye, a pyrylium-based dye, a perylene-based dye, a stilbene-based dye, a polythiophene-based dye, a rare earth complex-based phosphor, or the like.

### Injection Layer: Positive Hole Injection Layer, Electron Injection Layer

The injection layer is a layer provided between an electrode and the light-emitting layer in order to decrease a driving voltage and to enhance an emission luminance, and is detailed in Part 2, Chapter 2 “Denkyoku Zairyo” (pp. 123-166) of “Yuki EL Soshi To Sono Kogyoka Saizensen (Organic EL Element and Front of Industrialization thereof) (Nov. 30, 1998, published by N. T. S Co., Ltd.)”, and examples thereof include a positive hole injection layer and an electron injection layer.

The injection layer can be provided as necessary. The positive hole injection layer may be present between an anode (positive electrode) and the light-emitting layer or the positive transport layer, and the electron injection layer may be present between a cathode (negative electrode) and the light-emitting layer or the electron transport layer.

It is desirable that the electron injection layer is a very thin film, and the thickness thereof is within a range of 1 nm to 10 μm although the thickness depends on the material thereof.

### Positive Hole Transport Layer

The positive hole transport layer is made of a positive hole transport material having a function of transporting positive holes, and the positive hole injection layer and an electron-blocking layer are included in the positive hole transport layer, in a broad sense. The positive hole transport layer can be provided as a sole layer or as a plurality of layers. Furthermore, the positive hole transport layer may have a single layer structure constituted of one or two or more of the materials. The thickness of the positive hole transport layer is not particularly limited, but it is generally within a range about from 5 nm to 5 μm, preferably within a range from 5 nm to 200 nm.

The positive hole transport material is a material having a capability to inject or transport positive holes or an electron barrier property and may be either organic or inorganic. Furthermore, it is possible to enhance a p property by doping the material of the positive hole transport layer, with impurities. Preferably, the positive hole transport layer having a high p property makes it possible to produce an element which consumes lower electric power.

The positive hole transport layer can be formed by making the above-described positive hole transport material a thin film by a well-known method such as the vacuum vapor deposition method, the spin coating method, the casting method, the printing method including the inkjet method, or the LB method.

### Electron Transport Layer

The electron transport layer is made of a material having a function of transporting electrons, and the electron injection layer and a positive hole-blocking layer (not shown) are included in the electron transport layer, in a broad sense. The electron transport layer can be provided as a single layer structure or a laminated layer structure of a plurality of layers. Furthermore, the electron transport layer may have a single layer including one or more of materials. In addition, the thickness of the electron transport layer is not particularly limited, but the thickness is generally within a range of approximately 5 nm to 5 μm, preferably within a range of 5 nm to 200 nm.

In the electron transport layer having a single layer structure and the electron transport layer having a laminated layer structure, the electron transport material (also being the positive hole-blocking layer) constituting a portion of a layer adjacent to the light-emitting layer may have a function of transferr

### Electron Transport Layer

The electron transport layer is made of a material having a function of transporting electrons, and the electron injection layer and a positive hole-blocking layer (not shown) are included in the electron transport layer, in abroad sense. The electron transport layer can be provided as a single layer structure or a laminated layer structure of a plurality of layers. Furthermore, the electron transport layer may have a single layer including one or more of materials. In addition, the thickness of the electron transport layer is not particularly limited, but the thickness is generally within a range of approximately 5 nm to 5 μm, preferably within a range of 5 nm to 200 nm.

In the electron transport layer having a single layer structure and the electron transport layer having a laminated layer structure, the electron transport material (also being the positive hole-blocking layer) constituting a portion of a layer adjacent to the light-emitting layer may have a function of transferring electrons injected from the cathode to the light-emitting layer. An arbitrary compound can be selected for use from among previously well-known compounds, as such a material.

Furthermore, the above nitrogen-containing compound constituting the underlayer may be used as the material for the electron transport layer (electron transporting compound). This also applies to the electron transport layer serving also as the electron injection layer, and a similar material to the material constituting the underlayer described above may be used.

The electron transport layer can be formed by making the above-described electron transport material a thin film by the use of a well-known method such as the vacuum vapor deposition method, the spin coating method, the casting method, the printing method including the inkjet method or the LB method. [symbol] ing electrons injected from the cathode to the light-emitting layer. An arbitrary compound can be selected for use from among previously well-known compounds, as such a material.

Furthermore, the above nitrogen-containing compound constituting the underlayer may be used as the material for the electron transport layer (electron transporting compound). This also applies to the electron transport layer serving also as the electron injection layer, and a similar material to the material constituting the underlayer described above may be used.

The electron transport layer can be formed by making the above-described electron transport material a thin film by the use of a well-known method such as the vacuum vapor deposition method, the spin coating method, the casting method, the printing method including the inkjet method or the LB method.

### Blocking Layer: Positive Hole-Blocking Layer, Electron-Blocking Layer

The blocking layer is provided as necessary in addition to a basic constituent layer of a thin organic compound film as described above. Examples thereof include a positive hole-blocking layer described in documents such as Japanese Patent Laid-Open Nos. 11-204258 and 11-204359, and p. 237 of “Yuki EL Soshi To Sono Kogyoka Saizensen (Organic EL Element and Front of Industrialization thereof) (Nov. 30, 1998, published by N. T. S Co., Ltd.)”, and the like.

The positive hole-blocking layer has a function of the electron transport layer, in a broad sense. The positive hole-blocking layer is made of a positive hole-blocking material having remarkably a small capability to transport positive holes while having a function of transporting electrons, and can enhance a recombination probability of electrons and positive holes by blocking positive holes while transporting electrons. In addition, the configuration of an electron transport layer can be used for the positive hole-blocking layer, as necessary. Preferably, the positive hole-blocking layer is provided adjacent to the light-emitting layer.

On the other hand, the electron-blocking layer has a function of the positive hole transport layer, in abroad sense. The electron-blocking layer is made of a material having remarkably a small capability to transport electrons while having a function of transporting positive holes, and can enhance a recombination probability of electrons and positive holes by blocking electrons while transporting positive holes. Furthermore, the configuration of a positive hole transport layer can be used for the electron-blocking layer, as necessary. The thickness of the positive hole-blocking layer is preferably 3 to 100 nm, more preferably 5 to 30 nm.

### 2. Second Embodiment of Display Device

Next, the second embodiment of the display device of the field-sequential system will be explained. The second embodiment is different from the first embodiment only in the configuration of the organic EL element of the backlight. Accordingly, in the following explanation, only the configuration of the organic EL element will be explained, but the configuration of the display panel, and the like, and the overlapped explanation in each configuration will be omitted.

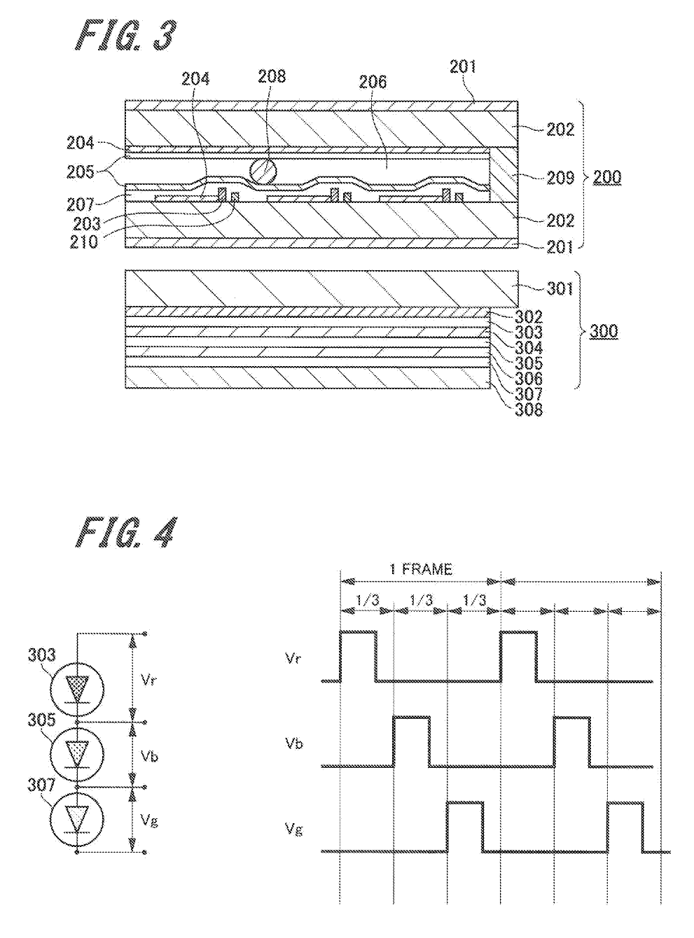

FIG. 3 is a schematic configuration view of the display device of the field-sequential system of the second embodiment. The display device of the field-sequential system shown in FIG. 3 includes the display panel 200 and a backlight 300 composed of an organic electroluminescence element (organic EL element).

In the display device of the field-sequential system shown in FIG. 3, the organic EL elements constituting the light-emitting portion of the backlight 300 has a so-called three-layered stacking structure in which the light-emitting units of three layers are laminated in the thickness direction (in the light-emitting direction). Furthermore, differently from the above-described first embodiment, the organic EL element does not have a partition wall made of an insulation material for distinguishing the organic EL element having a different color of light from each other, and is formed all over the region where the backlight 300 is provided.

Moreover, as shown in FIG. 3, the organic EL element constituting the backlight 300 is formed on a transparent substrate 301 by lamination of a first electrode 302, a first light-emitting unit 303, a first intermediate electrode 304, a second light-emitting unit 305, a second intermediate electrode 306, a third light-emitting unit 307, and a second electrode 308 in this order. In addition, in the organic EL element, the first electrode 302, the first intermediate electrode 304, the second intermediate electrode 306, and the second electrode 308 sandwich the first light-emitting unit 303, the second light-emitting unit 305, and the third light-emitting unit 307 therebetween, respectively, and one of the electrodes sandwiching the respective light-emitting units works as a cathode and the other works as an anode.

### First Electrode

The first electrode 302 is constituted of a transparent electrode. In a similar way to the first electrode of the first embodiment, the first electrode is constituted by the use of silver or an alloy containing silver as a principal component. Examples of the alloys each containing silver (Ag) as a principal component include silver magnesium (AgMg), silver copper (AgCu), silver palladium (AgPd), silver palladium copper (AgPdCu), silver indium (AgIn), and the like.

The thickness of the first electrode 302 is preferably within the range of 2 to 15 nm, more preferably within the range of 3 to 12 nm, and particularly preferably within the range of 4 to 9 nm. When the thickness is less than 15 nm, the absorbing components or the reflective components are small, and thus the light transmittance of the first electrode 102 becomes large. In addition, when the thickness is more than 2 nm, it is possible to sufficiently ensure the conductivity of the layer.

The transparent electrode is constituted by the use of silver or the alloy containing silver as a principal component is preferably formed on an underlayer. In a similar way to the first embodiment, the underlayer includes: a compound or the like which can suppress the aggregation of silver and which contains nitrogen atom or sulfur atom, in the deposition of, for example, the first electrode 302, the first intermediate electrode 304 and the second intermediate electrode 306 composed of silver or the alloy containing silver as a principal component, a layer containing metals such as Pd, Al, Ti, Pt and Mo which serve as a growth nucleus in the deposition of silver; and a layer containing zinc oxide.

### Intermediate Electrode

In the organic EL element, there are provided the first intermediate electrode 304 and the second intermediate electrode 306, between the first light-emitting unit 303, the second light-emitting unit 305, and the third light-emitting unit 307. Therefore, it is preferable that the first intermediate electrode 304 and the second intermediate electrode 306 have a small absorption component and reflection component of the layer, and have a large light transmittance.

A similar configuration to that of, for example, the above first electrode 302 can be applied to the first intermediate electrode 304 and the second intermediate electrode 306. A film of silver or an alloy containing silver can be used as a principal component, having a thickness of, for example, 2 to 15 nm. When a film of silver or an alloy containing silver as a principal component is formed as the first intermediate electrode 304 and the second intermediate electrode 306, each of the intermediate electrodes may be formed on the above underlayer, or may be directly formed on the organic material layer such as an electron transport layer constituting the light-emitting unit.

In addition, a film of aluminum having a thickness of, for example, 5 nm to 20 nm can be used as the first intermediate electrode 304 and the second intermediate electrode 306. Furthermore, it is possible to adopt a configuration in which the aluminum and the above silver or the alloy containing silver as a principal component are laminated, and a configuration in which the other conductive material is laminated.

Moreover, there can be used, as the first intermediate electrode 304 and the second intermediate electrode layer 306, an electrically conductive inorganic compound such as ITO (indium tin oxide), IZO (indium zinc oxide), ZnO₂, TiN, ZrN, HfN, TiOₓ, VOₓ, CuI, InN, GaN, CuAlO₂, CuGaO₂, SrCu₂O₂, LaB₆, or RuO₂, a two-layered film such as Au/Bi₂O₃, a multi-layered film such as SnO₂/Ag/SnO₂, ZnO/Ag/ZnO, Bi₂O₃/Au/Bi₂O₃, TiO₂/TiN/TiO₂, or TiO₂/ZrN/TiO₂, a fullerene such as C₆₀, and an electrically conductive organic layer such as oligothiophene, an electrically conductive organic compound layer such as metal phthalocyanine, metal-free phthalocyanine, metal porphyrin, or metal-free porphyrin, and the like.

### Second Electrode

The second electrode 308 is an electrode film seving as a counter electrode with respect to the transparent first electrode 302, the first intermediate electrode 304, and the second intermediate electrode 306. The second electrode 308 corresponds to the second electrode of the above first embodiment, and a similar configuration to that of the second electrode of the first embodiment is applicable. For example, there is used, as the second electrode 25, an electrode material having a low work function (4 eV or less) such as a metal (referred to as an electron-injecting metal), an alloy, an electrically conductive compound, or a mixture thereof.

### Light-Emitting Unit

Each of the first light-emitting unit 303, the second light-emitting unit 305 and the third light-emitting unit 307 has the light-emitting layer which emits light of predetermined color. Each of the light-emitting units contains at least a luminescent organic material, and for example, when the luminescent organic material has a light-emitting dopant of each color of blue (B), green (G) and red (R), any of the first light-emitting unit 303, the second light-emitting unit 305 and the third light-emitting unit 307 emits any color of R, G, and B. This corresponds to the stripe-like organic EL region and the light-emitting unit, which emit light of the respective colors of R, G, B in the above first embodiment. Accordingly, the first light-emitting unit 303, the second light-emitting unit 305 and the third light-emitting unit 307 can have similar configurations to those in the light-emitting units which emit red, green and blue lights, respectively, in the first embodiment.

According to the configuration, it is possible to individually emit light from the first light-emitting unit 303, the second light-emitting unit 305 and the third light-emitting unit 307, by individually controlling the first electrode 302 and the first intermediate electrode 304 which sandwich the first light-emitting unit 303, the first intermediate electrode 304 and the second intermediate electrode 306 which sandwich the second light-emitting unit 305, and the second intermediate electrode 306 and the second electrode 308 which sandwich the third light-emitting unit 307. Therefore, the organic EL element has a configuration in which an emission color can be freely regulated by controlling each light-emitting layer.

Furthermore, in the organic EL element, the first light-emitting unit 303, the second light-emitting unit 305 and the third light-emitting unit 307 may be laminated so that the diode properties thereof are arranged in the same direction, or in the different direction. For example, all of the first light-emitting unit 303, the second light-emitting unit 305 and the third light-emitting unit 307 may be laminated so as to have the same direction of the diode properties, or the first light-emitting unit 303 and the third light-emitting unit 307 may be laminated so as have the same direction of the diode properties, and only the second light-emitting unit 305 may be laminated so as have the different direction from the diode properties of the both light-emitting units.

### 3. Timing Chart

Next, FIG. 4 shows an equivalent circuit chart and a timing chart of the organic EL element.

Pairs of electrodes (the first electrode 302, the first intermediate electrode 304, the second intermediate electrode 306 and the second electrode 308 shown in FIG. 3) which sandwich the first light-emitting unit 303, the second light-emitting unit 305 and the third light-emitting unit 307, respectively are connected in parallel. Here, as an example, there will be explained a case where the first light-emitting unit 303 emits the red (R) light, the second light-emitting unit 305 emits the blue (B) light, and the third light-emitting unit 307 emits the green (G) light.

The timing chart shown in FIG. 4 shows the driving timing of the display panel and the light-emitting timing of each light-emitting unit of the organic EL element of the backlight. With respect to the organic EL region (pixel) , when each field of R, G and B is sequentially driven to thereby form one frame, the timing chart of the driving pulses of Vr, Vg and Vb is shown.

The light-emitting unit sequentially time-divides each color of R, G, B, for example, divides one frame into three equal portions (⅓ frame) to emit light of each color. Then, the display panel shields the time-divided light by synchronization for each of three primary colors, and the field image of each color which has been time-divided (R field, G field, B field) is sequentially formed.

Then, one frame image can be formed by temporal color mixture of the field image of each color time-divided.

Although, in the above-described timing chart, explanation has been made in a case where the ratio of the light emission period of each light-emitting unit of R, G and B is the same, the ratio of the light emission period of each light-emitting unit can also be arbitrarily changed.

Particularly, it is possible to prolong the life of the backlight by regulating each of the light emission period of R, G and B corresponding to the life of each light-emitting unit. At that time, it is preferable that a light emission period of a light-emitting unit having a relatively large deterioration (short life) with passage of time is made longer than the other light-emitting units. For example, it is preferable that the ratio of the light emission period of the light-emitting unit having the shortest life is made longest. Accordingly, it is possible to suppress the lowering of brightness of the backlight and change of chromaticity due to the deterioration with passage of time, and thus the reliability of the display device is enhanced.

### Effects

In the above display devices of the field-sequential system of the first embodiment and the second embodiment, silver or the alloy containing silver as a principal component is applied to the transparent electrode of the organic EL element, as the backlight. Accordingly, it is possible to form the electrode having a high light transmittance and a high electric conductivity, as the transparent electrode of the organic EL element. Namely, responsibility of Vr, Vg, Vb to the driving pulse can be increased in driving the light-emitting unit which emits each light of R, G, B color in the organic EL element, by enhancement of the conductivity of the electrode. As a result, even in time-division driving of at least about 1/180 second or less which is required for the backlight in the display device, it becomes possible to stably drive the organic EL element at a high speed. Accordingly, it is possible to configure the organic EL element which can cope with the high-speed driving, which is required for the driving of the display device of the field-sequential system. In addition, stable driving of the display device of the field-sequential system becomes possible.

Note that, in the above embodiments, although there has been explained the organic EL elements provided with the light-emitting units which can emit light of the three primary colors R, G and B, emission colors of the light-emitting units are not limited thereto. For example, there may be adopted a configuration of including a light-emitting unit which can emit light of complementary colors of yellow, cyan and magenta. Furthermore, in this case, there may be adopted a configuration of emitting light of the three primary colors by synthesizing those complementary colors. Moreover, there may be adopted a configuration in which a light-emitting unit that can emit light of any of the three primary colors is combined with a light-emitting unit that can emit light of any of the complementary colors.

Note that the present invention is not limited to the configurations explained in the above embodiments, and other various modifications and changes are possible within the scope not departing from the other configurations of the present invention.

### REFERENCE SIGNS LIST

100, 300 Backlight

101, 202, 301 Transparent substrate

102, 302 First electrode

102r, 102g, and 102b First terminal

103r, 103g, and 103b Light-emitting unit

104,308 Second electrode

108 Partition wall

109r, 109g, and 109b Organic EL region

111 Second terminal

200 Display panel

201 Polarizing plate

203 Thin film transistor

204 Pixel electrode

205 Oriented film

206 Liquid crystal layer

207 Insulating layer

208 Spacer

209 Seal

210 Data line

303 First light-emitting unit

304 First intermediate electrode

305 Second light-emitting unit

306 Second intermediate electrode

306 Second intermediate electrode

307 Third light-emitting unit

1. A display device comprising a backlight and a field-sequential display panel, wherein
a light-emitting portion of the backlight is an organic electroluminescence element including a plurality of light-emitting units that emit light of different colors, and
at least one electrode of the organic electroluminescence element is made of Ag or an alloy containing Ag as a principal component.

2. The display device according to claim 1, wherein the organic electroluminescence element has a configuration in which the light-emitting units that emit light of different colors are laminated.

3. The display device according to claim 1, wherein, in the light-emitting portion, the organic electroluminescence element that emits light of different colors is arranged in the direction of the light-emitting surface.

4. The display device according to claim 1, wherein the electrode formed on a side closest to the display panel includes Ag or an alloy containing Ag as a principal component.

5. The display device according to claim 1, wherein the electrode including Ag or an alloy containing Ag as a principal component is formed on an underlayer including a compound containing nitrogen atom.

6. The display device according to claim 2, wherein, in the organic electroluminescence element in which the light-emitting units are laminated, an intermediate electrode formed between the laminated light-emitting units includes Ag or an alloy containing Ag as a principal component.

7. The display device according to claim 1, wherein, in a plurality of the light-emitting units which emits light of different colors, a ratio of a light emission period of a first light-emitting unit is different from a ratio of a light emission period of a second light-emitting unit which emits light of other color.
